(19) United States
(12) Patent Application Publication
(10) Pub. No.: US 2013/0087375 A1
(43) Pub. Date: Apr. 11, 2013

(54) MULTILAYER WIRING SUBSTRATE, ELECTRONIC DEVICE, AND MANUFACTURING METHOD OF MULTILAYER WIRING SUBSTRATE

(71) Applicant: FUJITSU LIMITED, Kawasaki-shi (JP)

(72) Inventor: Kazuhisa TSUNOI, Yokohama (JP)

(73) Assignee: FUJITSU LIMITED, Kawasaki-shi (JP)

(21) Appl. No.: 13/624,589

(22) Filed: Sep. 21, 2012

(30) Foreign Application Priority Data
Oct. 7, 2011 (JP) 2011-223047

(51) Int. Cl. H05K 1/02; H05K 13/00; H05K 1/16

(52) U.S. Cl. 174/260; 174/250; 29/825

(57) ABSTRACT

There is provided a multilayer wiring substrate that includes a plurality of insulator layers, and electric conductors, the electric conductors and the plurality of insulator layers being configured to be stacked alternately, wherein a plurality of holes are formed from a surface of the multilayer wiring substrate in a thickness direction of the multilayer wiring substrate, the holes being formed leaving at least one of the insulators.

### CROSS-REFERENCE TO RELATED APPLICATION

This application is based upon and claims the benefit of priority of the prior Japanese Patent Application No. 2011-223047, filed on Oct. 7, 2011, the entire contents of which are incorporated herein by reference.

### FIELD

The embodiments discussed herein are related to a multilayer wiring substrate, an electronic device, and a manufacturing method of multilayer wiring substrate.

### BACKGROUND

There has been used a thin plate-shaped printed circuit material which includes a base and a conductive foil boned to a surface of the base, where the base is made of a rigid sheet. The base of the printed circuit material is provided with a bending work groove that facilitates a bending work.

A portion surrounding the base on which the bending work groove is formed is punched out and the base is divided by the bending work groove. Thereafter, a lining sheet and a copper foil are attached to the divided base and the printed circuit material is bent so that the bending work groove is located inside or outside.

Japanese Laid-open Patent Publication No. 1980-099789 is an example of related art.

### SUMMARY

According to an aspect of the invention, a multilayer wiring substrate includes a plurality of insulator layers, and electric conductors, the electric conductors and the plurality of insulator layers being configured to be stacked alternately, wherein a plurality of holes are formed from a surface of the multilayer wiring substrate in a thickness direction of the multilayer wiring substrate, the holes being formed leaving at least one of the insulators.

a multilayer wiring substrate includes a plurality of insulators, electric conductors configured to be stacked alternately with the insulators, and a plurality of holes formed from a surface of the multilayer wiring substrate in a thickness direction of the multilayer wiring substrate, the holes being formed leaving at least one of the insulators.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view illustrating a state in which a wiring substrate of a comparative example is disposed inside a housing of an electronic device.

FIG. 2 is a diagram illustrating a rigid flexible substrate;

FIG. 3A is a perspective view illustrating a mobile phone terminal 500 including a multilayer wiring substrate 100 of a first embodiment;

FIG. 3B is a transparent perspective view illustrating the mobile phone terminal 500 including the multilayer wiring substrate 100 of the first embodiment;

FIG. 3C is a cross-sectional view taken along line IIIC-IIIC in FIG. 3B;

FIG. 4A is a perspective view illustrating a cross section structure of the multilayer wiring substrate 100 of the first embodiment;

FIG. 4B is a perspective view illustrating a cross section structure of the multilayer wiring substrate 100 of the first embodiment;

FIG. 5 is a cross-sectional view illustrating a state in which the multilayer wiring substrate 100 of the first embodiment is bent;

FIG. 6A is a perspective view illustrating a process for forming holes 41A to 41B and 51A to 55A in the multilayer wiring substrate 100 of the first embodiment;

FIG. 6B is a perspective view illustrating a process for forming holes 41A to 41B and 51A to 55A in the multilayer wiring substrate 100 of the first embodiment;

FIG. 6C is a perspective view illustrating a process for forming holes 41A to 41B and 51A to 55A in the multilayer wiring substrate 100 of the first embodiment;

FIG. 7A is diagram illustrating a bending process for bending the multilayer wiring substrate 100 of the first embodiment;

FIG. 7B is diagram illustrating a bending process for bending the multilayer wiring substrate 100 of the first embodiment;

FIG. 7C is diagram illustrating a bending process for bending the multilayer wiring substrate 100 of the first embodiment;

FIG. 7D is a front view illustrating one of tools used in the process illustrated in FIG. 7A;

FIG. 8A is a perspective view illustrating a cross section structure of a multilayer wiring substrate 200 of a second embodiment; and

FIG. 8B is a perspective view illustrating a cross section structure of the multilayer wiring substrate 200 of the second embodiment.

### DESCRIPTION OF EMBODIMENTS

In a conventional printed circuit material, a bending work groove is formed on a rigid sheet, and thereafter a portion surrounding the rigid sheet is punched out to divide the rigid sheet by the bending work groove, and then a lining sheet and a copper foil are attached to the divided rigid sheet.

Therefore, a substrate such as the conventional printed circuit material has a problem that the number of processes for manufacturing a bent structure is large and a substrate having a bent structure is difficult to manufacture.

Therefore, it is preferable to provide a multilayer wiring substrate, an electronic device, and a manufacturing method of multilayer wiring substrate, where a bent structure is easily manufactured.

Hereinafter, embodiments to which a multilayer wiring substrate, an electronic device, and a manufacturing method of multilayer wiring substrate of the present disclosure are applied will described.

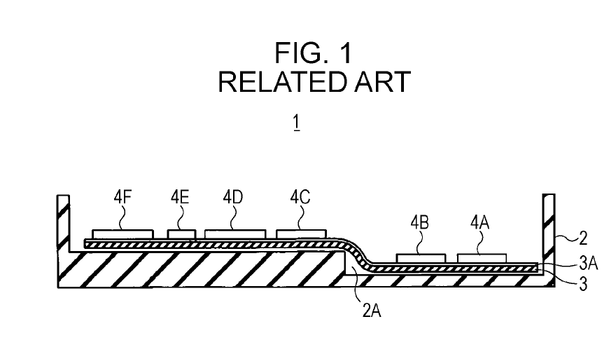

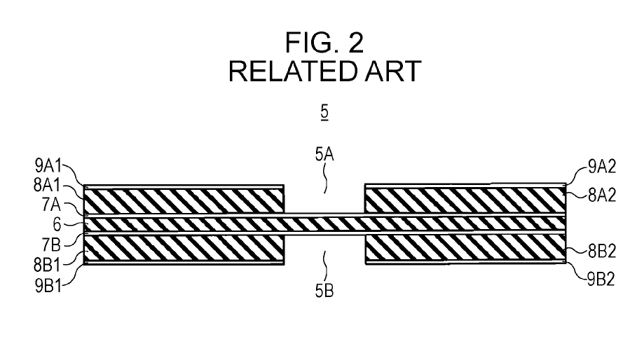

Before describing the multilayer wiring substrate, the electronic device, and the manufacturing method of multilayer wiring substrate of the embodiments, a problem of a wiring substrate of a comparative example will be described with reference to FIGS. 1 and 2.

In an electronic device such as a mobile phone terminal, a digital camera, and a digital video camera, electronic components such as a CPU (Central Processing Unit), a memory, and other peripheral devices are mounted on a wiring substrate.

As a wiring substrate, for example, there are an FR4 (Flame Retardant type 4) substrate where an epoxy resin is impregnated into glass fibers and a thermal curing process is performed and a wiring substrate in which a thermal curing process is performed on thermosetting polyimide.

For example, an electronic device such as a mobile phone terminal, a digital camera, and a digital video camera is small, so that an internal space of a housing which houses a wiring substrate is limited.

However, a thermal curing process is performed on the entire wiring substrate described above, so that the wiring substrate is a rigid type wiring substrate having high rigidity. Therefore, the wiring substrate is not suited to a situation where the substrate is bent.

Therefore, in a small electronic device, to effectively use space inside a housing, a small device is provided with a wiring substrate to be easily bent instead of a rigid type wiring substrate for effective use of space inside a housing and electronic components such as a CPU are mounted on the wiring substrate to be easily bent.

As a wiring substrate that may be easily bent, for example, there are a flexible substrate and a rigid flexible substrate.

The flexible substrate is formed of a flexible film made of polyimide, so that the flexible substrate may be bent at any position and may be bent relatively freely.

The rigid flexible substrate is a substrate in which a flexible substrate is partially used to be able to be bent and a rigid type substrate is used in the other part.

FIG. 1 is a cross-sectional view illustrating a state in which the wiring substrate of the comparative example is disposed inside a housing of an electronic device. An electronic device 1 illustrated in FIG. 1 is, as an example, a mobile phone terminal.

Inside a housing 2 of the electronic device 1, a flexible substrate 3 bent along a level difference 2A inside the housing 2 is disposed.

An electric conductor 3A is patterned on a surface (an upper surface in FIG. 1) of the flexible substrate 3. The electric conductor 3A is formed by, for example, patterning a copper foil formed on the front surface of the flexible substrate 3 by an etching process or the like. From the viewpoint of easy understanding, FIG. 1 illustrates the electric conductor 3A on the entire surface of the flexible substrate 3. However, actually, the electric conductor 3A is patterned according to positions of terminals and the like of electronic components mounted on the flexible substrate 3.

On the flexible substrate 3, as electronic components, an RF (Radio Frequency) communication unit 4A, an AD (Analog/Digital) converter 4B, a baseband processor 4C, a CPU 4D, an I/F (Inter Face) 4E, and a memory 4F are mounted. Electrical connections among electronic components 4A to 4F are allowed by the electric conductor 3A.

The flexible substrate 3 formed of a flexible film made of polyimide may be allowed to be bent along the level difference 2A inside the housing 2, so that it is possible to effectively use the internal space of the housing 2 of the small electronic device 1.

The flexible substrate 3 has flexibility in the entire substrate, so that the flexible substrate 3 is suited to, in particular, a usage in which there are many spatial restrictions and there are many portions at which the substrate is bent.

Next, the rigid flexible substrate will be described with reference to FIG. 2.

FIG. 2 is a diagram illustrating the rigid flexible substrate.

The rigid flexible substrate 5 includes a flexible substrate 6, electric conductors 7A and 7B, rigid substrates 8A1, 8A2, 8B1, and 8B2, and electric conductors 9A1, 9A2, 9B1, and 9B2.

The flexible substrate 6 is formed of, for example, a flexible film made of polyimide and may be bent at bending portions 5A and 5B where the rigid substrates 8A1, 8A2, 8B1, and 8B2 are absent.

The electric conductors 7A and 7B are formed on the front surface (the front surface in FIG. 2) and the back surface (the back surface in FIG. 2) of the flexible substrate 6, respectively. The electric conductors 7A and 7B are formed by, for example, patterning a copper foil formed on the front and back surfaces of the flexible substrate 6 by an etching process or the like. From the viewpoint of easy understanding, FIG. 2 illustrates the electric conductors 7A and 7B on the entire front surface and the entire back surface of the flexible substrate 6. However, actually, the electric conductors 7A and 7B are patterned according to positions of terminals and the like of electronic components mounted on the flexible substrate 6.

The rigid substrates 8A1 and 8A2 are formed on the front surface of the electric conductor 7A so as to position the bending portion 5A of the rigid flexible substrate 5 therebetween. The rigid substrates 8B1 and 8B2 are formed on the back surface of the electric conductor 7B so as to position the bending portion 5B of the rigid flexible substrate 5 therebetween.

The rigid substrates 8A1, 8A2, 8B1, and 8B2 are an FR4 (Flame Retardant type 4) substrate where an epoxy resin is impregnated into glass fibers and is performed under a thermal curing process.

The electric conductor 9A1 and 9A2 are formed on the front surfaces of the rigid substrates 8A1 and 8A2 respectively. The electric conductor 9B1 and 9B2 are formed on the back surfaces of the rigid substrates 8B1 and 8B2 respectively.

The electric conductors 9A1, 9A2, 9B1, and 9B2 are formed by, for example, patterning a copper foil formed on the front surface (upper surface) or the back surface (lower surface) of the rigid substrates 8A1, 8A2, 8B1, and 8B2 by an etching process or the like, respectively. From the viewpoint of easy understanding, FIG. 2 illustrates the electric conductors 9A1, 9A2, 9B1, and 9B2 on the entire front surface (upper surface) or the entire back surface (lower surface) of the rigid substrates 8A1, 8A2, 8B1, and 8B2. However, actually, the electric conductors 9A1, 9A2, 9B1, and 9B2 are patterned according to positions of terminals and the like of electronic components mounted on the rigid substrates 8A1, 8A2, 8B1, and 8B2.

The rigid flexible substrate 5 may not be bent at portions where the rigid substrates 8A1, 8A2, 8B1, and 8B2 are present. However, the rigid flexible substrate 5 may be bent at bending portions 5A and 5B where the rigid substrates 8A1, 8A2, 8B1, and 8B2 are absent.

For example, when the bending portion 5A is valley-folded and the bending portion 5B is mountain-folded, the rigid flexible substrate 5 may be folded into a U-shape. On the other hand, when the bending portion 5A is mountain-folded and the bending portion 5B is valley-folded, the rigid flexible substrate 5 may be folded into a reverse U-shape.

The bending portions 5A and 5B may be bent so that a level difference is absorbed between the rigid substrates 8A1, 8B1 illustrated on the left side of FIG. 2 and the rigid substrates 8A2, 8B2 illustrated on the right side of FIG. 2. In other words, the rigid flexible substrate 5 may be bent into a shape like the flexible substrate 3 illustrated in FIG. 1.

In this way, the rigid flexible substrate 5 may be bent freely at the bending portions 5A and 5B, so that, for example, even when there is a level difference 2A as in the housing 2 of the small electronic device 1 (see FIG. 1), space may be effectively used.

In the flexible substrate 3 made of polyimide, a hole such as a via is made by using a mold or the like. However, the rigid substrates 8A1, 8A2, 8B1, and 8B2 of the rigid flexible substrate 5 are rigid, so that a hole such as a via may be made by laser beam machining, drilling, or the like.

Therefore, the rigid flexible substrate 5 may be processed more finely than the flexible substrate 3, so that it is possible to improve packaging density or to realize high-density in the rigid substrates 8A1, 8A2, 8B1, and 8B2.

In the rigid flexible substrate 5, it is possible to form the electric conductors 9A1, 9A2, 9B1, and 9B2 on the front surface or the back surface of the rigid substrates 8A1, 8A2, 8B1, and 8B2, so that there is an advantage that the number of layers of the rigid flexible substrate 5 may be greater than that of the flexible substrate 3.

In this way, the rigid flexible substrate 5 has an advantage that the packaging density and the number of layers of the rigid flexible substrate 5 may be greater than those of the flexible substrate 3 (see FIG. 1), although the rigid flexible substrate 5 has a limitation of positions at which the rigid flexible substrate 5 may be bent as compared with the flexible substrate 3.

The flexible substrate 3 (see FIG. 1) and the rigid flexible substrate 5 (see FIG. 2) of the comparative examples may effectively use space by being bent, so that they are often used in the small electronic device 1.

However, the flexible substrate 3 and the rigid flexible substrate 5 are 1.5 to 2 times expensive than a wiring substrate entirely made of a rigid material when obtaining the same wiring pattern. The difference of manufacturing cost is mainly due to a difference of material cost.

The difference of manufacturing cost also appears as a difference of cost of the electronic device 1 as an end product.

As described above, the manufacturing costs of the flexible substrate 3 and the rigid flexible substrate 5 of the comparative examples are higher than that of a rigid type wiring substrate. Nevertheless, the flexible substrate 3 and the rigid flexible substrate 5 are often used in the small electronic device 1 because the space inside the housing 2 is becoming more and more limited as the electronic device 1 is downsized.

If the rigid type wiring substrate may be easily bent, the cost may be reduced, so that such a rigid type wiring substrate is promising as an alternative of the flexible substrate 3 and the rigid flexible substrate 5 of the comparative examples. However, there is a problem that such a wiring substrate is not realized.

Therefore, a wiring substrate, an electronic device, and a manufacturing method of wiring substrate of a first embodiment and a second embodiment, which solve the above problem, will be described below.

### First Embodiment

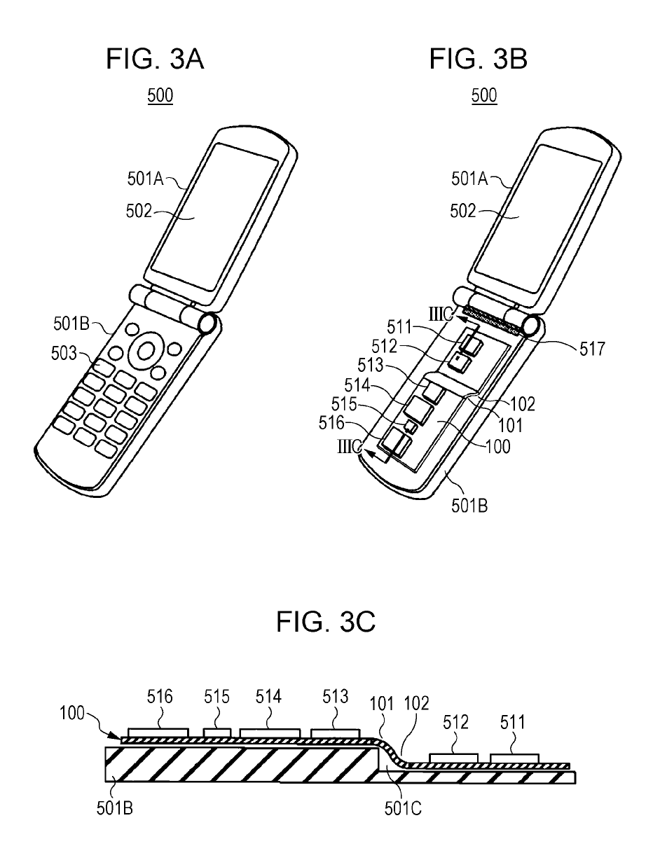

FIGS. 3A and 3B are perspective views illustrating a mobile phone terminal 500 including a multilayer wiring substrate 100 of a first embodiment. FIG. 3A illustrates a state in which housings 501A and 501B of the foldable mobile phone terminal 500 are opened. From the viewpoint of easy understanding, FIG. 3B illustrates the inside of the mobile phone terminal 500 as a transparent perspective view. FIG. 3C illustrates the housing 501B and the multilayer wiring substrate 100 along IIIC-IIIC cross section in FIG. 3B. Here, the mobile phone terminal 500 is an example of the electronic device.

As illustrated in FIG. 3A, the housings 501A and 501B of the mobile phone terminal 500 are provided with a display unit 502 and an operation unit 503 respectively. As illustrated in FIG. 3B, the multilayer wiring substrate 100 is housed inside the housing 501B.

The housings 501A and 501B are made of resin or metal and include openings into which the display unit 502 and the operation unit 503 are disposed respectively. The display unit 502 may be, for example, a liquid crystal panel that may display characters, numbers, and images. The operation unit 503 includes various selection keys for selecting functions of the mobile phone terminal 500 in addition to a numerical pad. The mobile phone terminal 500 may include an attachment device such as a proximity communication device (an infra-red communication device, a communication device for electronic money, and the like) or a camera.

On the multilayer wiring substrate 100 illustrated in FIG. 3B, an RF (Radio Frequency) communication unit 511, an AD (Analog/Digital) converter 512, a baseband processor 513, a CPU 514, an I/F (Inter Face) 515, and a memory 516. Each electronic component (511 to 516) is electrically connected to each other by an electric conductor of the multilayer wiring substrate 100. The housing 501B includes an antenna 517. The antenna 517 is connected to an RF communication unit 511.

A signal for communication received by the antenna 517 is processed by a filtering process and the like in the RF communication unit 511, and then converted into a digital signal by the AD converter 512. To the digital signal outputted from the AD converter 512, a baseband process is performed by the baseband processor 513, and then the signal is outputted as a voice from a speaker, not illustrated in the drawings, through the CPU 514. The CPU 514 accesses the memory 516 through the IF 515, reads an appropriate program, and executes the program when processing the signal representing the voice.

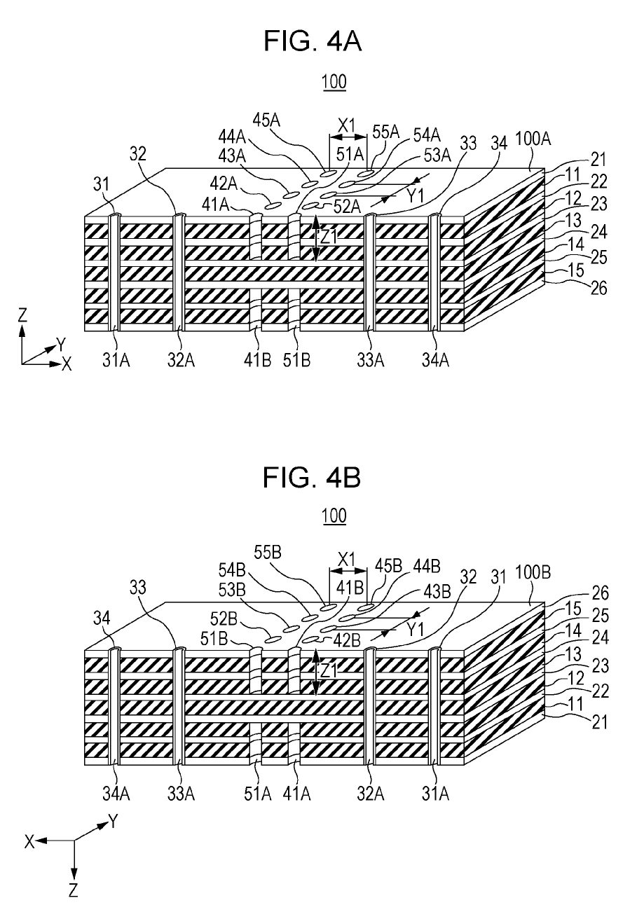

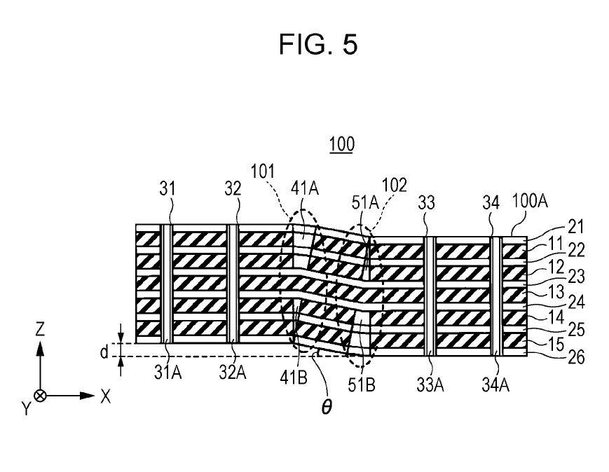

As illustrated in FIGS. 3B and 3C, the multilayer wiring substrate 100 is bent at two bending portions 101 and 102. As illustrated in FIG. 3C, the bending portions 101 and 102 are bent along a level difference 501C in the housing 501B. This is to effectively use space inside the housing 501B including the level difference 501C. A specific configuration of the multilayer wiring substrate 100 will be described later with reference to FIGS. 4A, 4B, and 5.

Although, in FIG. 3, the mobile phone terminal 500 is illustrated as an example of the electronic device, the electronic device is not limited to the mobile phone terminal 500, and for example, the electronic device may be a small electronic device such as a digital camera and a digital video camera.

FIGS. 4A and 4B are perspective views illustrating a cross section structure of the multilayer wiring substrate 100 of the first embodiment. FIG. 4A is a perspective view illustrating the multilayer wiring substrate 100 as seen from the front surface 100A, and FIG. 4B is a perspective view illustrating the multilayer wiring substrate 100 as seen from the back surface 100B.

A cross section structure of the multilayer wiring substrate 100 illustrated in FIGS. 4A and 4B is an enlarged view of a part of a cross section of the multilayer wiring substrate 100 before being bent at the bending portions 101 and 102 (see FIGS. 3B and 3C).

Here, as illustrated in FIGS. 4A and 4B, an XYZ coordinate, which is a three-dimensional coordinate, is defined. The XYZ coordinate is a coordinate system for representing a position of each constituent element of the multilayer wiring substrate 100.

A direction of the IIIC-IIIC cross section in FIG. 3B corresponds to an X axis direction in FIGS. 4A and 4B. The X axis direction corresponds to the longitudinal direction of the multilayer wiring substrate 100, a Y axis direction corresponds to the short direction of the multilayer wiring substrate 100, and a Z axis direction corresponds to the thickness direction of the multilayer wiring substrate 100.

The multilayer wiring substrate 100 of the first embodiment includes five layers of insulators 11, 12, 13, 14, and 15, six layers of electric conductors 21, 22, 23, 24, 25, and 26, and vias 31, 32, 33, and 34. The multilayer wiring substrate 100 further includes holes 41A, 42A, 43A, 44A, 45A, 41B, 42B, 43B, 44B, 45B, 51A, 52A, 53A, 54A, 55A, 51B, 52B, 53B, 54B, and 55B.

The multilayer wiring substrate 100 is, for example, a rigid type printed circuit board (PCB) formed of a glass fabric board material such as FR4 (Flame Retardant Type 4) and FR5 (Flame Retardant Type 5) and an epoxy resin.

The multilayer wiring substrate 100 is not limited to FR4 or FR5, but may be another grade substrate of the FR standard or may be a substrate of another standard.

The insulators 11, 12, 13, 14, and 15 (hereinafter referred to as insulators 11 to 15) may be divided into two groups. For example, the insulators 11, 13, and 15 are layers formed by impregnating thermosetting resin into fibers. Specifically, the insulators 11, 13, and 15 are, for example, a prepreg in which an epoxy resin is impregnated into a glass fabric board material. The insulators 12 and 14 are cores realized by a fiber layer. However, any prepreg and any core that may maintain heat dissipation performance and strength may be used. The prepreg and the core may be formed by impregnating an epoxy resin into a glass fabric board material, mixing fillers into an epoxy resin, or using an epoxy resin including no fiber.

The electric conductors 21, 22, 23, 24, 25, and 26 (hereinafter referred to as electric conductors 21 to 26) are, for example, a copper foil. However, there are electric conductors in which a copper foil is coated. For example, the electric conductors 21 to 26 are used as a wiring layer, a power supply layer, a ground layer, and the like.

In the above example, the insulators 11, 13, and 15 are grouped into a prepreg group and the insulators 12 and 14 are grouped into a core group. However, the grouping is not limited to this. For example, the insulator 13 may be grouped into a core group and the insulators 11, 12, 14, and 15 may be grouped into a prepreg group. Further, all the insulators 11, 12, 13, 14, and 15 may be grouped into a prepreg group.

The insulators 11 to 15 and the electric conductors 21 to 26 are firmly fixed by forming the electric conductors 22 and 23 and the electric conductors 24 and 25, respectively, on both sides of the insulator 12 and the insulator 14, which are a core, and performing a thermal curing process.

The vias 31, 32, 33, and 34 (hereinafter referred to as vias 31 to 34) are cylindrically formed along an internal wall of through-holes 31A, 32A, 33A, and 34A (hereinafter referred to as through-holes 31A to 34A). The vias 31 to 34 extend in the Z axis direction and are connected to all the electric conductors 21 to 26.

The vias 31 to 34 are formed by, for example, forming through-holes 31A to 34A in the insulators 11 to 15 and the electric conductors 21 to 26, which are bonded together by a thermosetting process, forming an electroless plating layer on an inner wall of the through-holes 31A to 34A, and forming an electroplating layer on the electroless plating layers.

The electroless plating layer and the electroplating layer, which form the vias 31 to 34, may be formed by copper plating. However, the plating for forming the vias 31 to 34 is not limited to the copper plating, but may be plating of other materials (for example, nickel, tin, zinc, and the like).

Here, FIGS. 4A and 4B illustrate a state in which all the vias 31 to 34 included in the multilayer wiring substrate 100 are connected to all the electric conductors 21 to 26. However, the vias 31 to 34 may be connected to any one of the electric conductors 21 to 26. When the electric conductors 21 to 26 are not connected to the vias 31 to 34, a plan view shape of the electric conductors 21 to 26 is patterned to avoid a via (any one of the vias 31 to 34).

As illustrated in FIG. 4A, the holes 41A, 42A, 43A, 44A, and 45A (hereinafter referred to as holes 41A to 45A) are arranged in the Y axis direction and formed in the Z axis minus direction from the front surface 100A.

Each of the holes 41A to 45A passes through the electric conductor 21, the insulator 11, the electric conductor 22, and insulator 12 from the front surface 100A and reaches the front surface (upper surface in FIG. 4A) of the electric conductor 23.

As illustrated in FIG. 4B, the holes 41B, 42B, 43B, 44B, and 45B (hereinafter referred to as holes 41B to 45B) are arranged in the Y axis direction and formed in the Z axis plus direction from the back surface 100B.

Each of the holes 41B to 45B passes through the electric conductor 26, the insulator 15, the electric conductor 25, and insulator 14 from the back surface 100B and reaches the front surface (upper surface in FIG. 4B) of the electric conductor 24.

The positions where the holes 41B to 45B are formed in the XY plane are the same as the positions of the holes 41A to 45A in the XY plane, respectively.

As illustrated in FIG. 4A, the holes 51A, 52A, 53A, 54A, and 55A (hereinafter referred to as holes 51A to 55A) are arranged in the Y axis direction and formed in the Z axis minus direction from the front surface 100A.

Each of the holes 51A to 55A passes through the electric conductor 21, the insulator 11, the electric conductor 22, and insulator 12 from the front surface 100A and reaches the front surface (upper surface in FIG. 4A) of the electric conductor 23.

As illustrated in FIG. 4B, the holes 51B, 52B, 53B, 54B, and 55B (hereinafter referred to as holes 51B to 55B) are arranged in the Y axis direction and formed in the Z axis plus direction from the back surface 100B.

Each of the holes 51B to 55B passes through the electric conductor 26, the insulator 15, the electric conductor 25, and insulator 14 from the back surface 100B and reaches the front surface (upper surface in FIG. 4B) of the electric conductor 24.

The positions where the holes 51B to 55B are formed in the XY plane are the same as the positions of the holes 51A to 55A in the XY plane, respectively.

In this way, the holes 41A to 45A and the holes 41B to 45B are formed in the thickness direction (Z axis direction) of the multilayer wiring substrate 100 while leaving the electric conductor 23, the insulator 13, and the electric conductor 24.

Similarly, the holes 51A to 55A and the holes 51B to 55B are formed in the thickness direction (Z axis direction) of the multilayer wiring substrate 100 while leaving the electric conductor 23, the insulator 13, and the electric conductor 24.

Each of the holes 41A to 45A and the holes 41B to 45B is an example of a hole formed from the front surface 100A and the back surface 100B of the multilayer wiring substrate 100 while leaving the electric conductor 23, the insulator 13, and the electric conductor 24.

Each of the holes 51A to 55A and the holes 51B to 55B is an example of a hole formed from the front surface 100A and the back surface 100B of the multilayer wiring substrate 100 while leaving the electric conductor 23, the insulator 13, and the electric conductor 24.

The holes 41A to 45A, 41B to 45B, 51A to 55A, and 51B to 55B are formed by laser beam machining described later after the multilayer wiring substrate 100 including the insulators 11 to 15, the electric conductors 21 to 26, and the vias 31 to 34 is completed. Therefore, it is possible to select positions where the holes 41A to 45A, 41B to 45B, 51A to 55A, and 51B to 55B are formed after the multilayer wiring substrate 100 is completed.

Here, the diameter of each of the holes 41A to 45A, 41B to 45B, 51A to 55A, and 51B to 55B is set to, for example, one in the range 50 μm to 400 μm.

A distance Y1 in the Y axis direction between adjacent holes of the holes 41A to 45A, 41B to 45B, 51A to 55A, and 51B to 55B is set to, for example, 1 mm.

The distances X1 in the X axis direction between the centers of the holes 41A to 45A and the centers of the holes 51A to 55A are set to 5 mm respectively, as illustrated in FIG. 4A. The distances in the X axis direction between the centers of the holes 41B to 45B and the centers of the holes 51B to 55B are also X1, which is set to 5 mm, as illustrated in FIG. 4A.

The depth Z1 of each of the holes 41A to 45A, 41B to 45B, 51A to 55A, and 51B to 55B is set to, for example, 0.1 mm. The depth Z1 is a depth from the front surface 100A to the back surface 100B of the multilayer wiring substrate 100.

In the multilayer wiring substrate 100, a stress is applied to both sides of the holes 41A to 45A and 41B to 45B to bend the multilayer wiring substrate 100 so as to mountain-fold a portion in which the holes 41A to 45A are formed and valley-fold a portion in which the holes 41B to 45B are formed.

As a result, the electric conductor 21, the insulator 11, the electric conductor 22, and insulator 12 are severed or stretched along the holes 41A to 45A and the electric conductor 26, the insulator 15, the electric conductor 25, and insulator 14 are compressed along the holes 41B to 45B.

Thereby, the multilayer wiring substrate 100 is mountain-folded at the portion in which the holes 41A to 45A are formed and valley-folded at the portion in which the holes 41B to 45B are formed, so that the electric conductor 23, the insulator 13, and the electric conductor 24 are bent.

Also, a stress is applied to both sides of the holes 51A to 55A and 51B to 55B so as to mountain-fold a portion in which the holes 51A to 55A are formed and valley-fold a portion in which the holes 51B to 55B are formed.

As a result, the electric conductor 21, the insulator 11, the electric conductor 22, and insulator 12 are compressed along the holes 51A to 55A and the electric conductor 26, the insulator 15, the electric conductor 25, and insulator 14 are severed or stretched along the holes 51B to 55B.

Thereby, the multilayer wiring substrate 100 is valley-folded at the portion in which the holes 51A to 55A are formed and mountain-folded at the portion in which the holes 51B to 55B are formed, so that the electric conductor 23, the insulator 13, and the electric conductor 24 are bent.

FIG. 5 illustrates a state in which the multilayer wiring substrate 100 is bent as described above.

FIG. 5 is a cross-sectional view illustrating a state in which the multilayer wiring substrate 100 of the first embodiment is bent. The cross section illustrated in FIG. 5 is a cross section including the holes 41A, 41B, 51A, and 51B and vias 31 to 34 illustrated in FIG. 4A.

As illustrated in FIG. 5, the multilayer wiring substrate 100 is bent so that the multilayer wiring substrate 100 is mountain-folded at a portion in which the holes 41A and 51B are formed and is valley-folded at a portion in which the holes 41B and 51A are formed.

In other words, in the cross section illustrated in FIG. 5, a portion indicated by a dashed line including the hole 41A and 41B is the bending portion 101 (see FIGS. 3B and 3C) and a portion indicated by a dashed line including the hole 51A and 51B is the bending portion 102 (see FIGS. 3B and 3C).

Although FIG. 5 illustrates a cross section including holes 41A, 41B, 51A, and 51B, the multilayer wiring substrate 100 is bent so as to be mountain-folded along the holes 41A to 45A and 51B to 55B and valley-folded along the holes 41B to 45B and 51A to 55A.

In other words, the bending portion 101 is formed in a portion including the holes 41A to 45A and 41B to 45B along the Y axis. Similarly, the bending portion 102 is formed in a portion including the holes 51A to 55A and 51B to 55B along the Y axis.

In this way, the multilayer wiring substrate 100 is bent at the bending portion 101 and 102, so that, as illustrated in FIG. 5, on the back surface 100B of the multilayer wiring substrate 100, a level difference having a height d may be formed between the left side portion and the right side portion of the multilayer wiring substrate 100.

The height d of the level difference of the multilayer wiring substrate 100 is determined by the thickness of the insulators 11 to 15, the thickness of the electric conductors 21 to 26, the distance X1 between the holes 41A to 45A and 41B to 45B and the holes 51A to 55A and 51B to 55B, the diameter and the depth Z1 of the holes, and the like.

Here, as illustrated in FIG. 5, when the multilayer wiring substrate 100 is bent so that the portion on the left side of the holes 41A to 45A and the 41B to 45B and the portion on the right side of the holes 51A to 55A and the 51B to 55B are in parallel with the X axis, an angle θ is defined as illustrated in FIG. 5.

The angle θ is an angle between the portion on the right side of the holes 51A to 55A and the 51B to 55B and the portion between the holes 41A to 45A and 41B to 45B and the holes 51A to 55A and 51B to 55B in the multilayer wiring substrate 100. Although not illustrated in FIG. 5, an angle between the portion on the left side of the holes 41A to 45A and the 41B to 45B and the portion between the holes 41A to 45A and 41B to 45B and the holes 51A to 55A and 51B to 55B in the multilayer wiring substrate 100 is also θ.

When using the angle θ, the height d of the level difference of the multilayer wiring substrate 100 may be obtained as a height substantially the same as d=X1×tan θ. For example, when the X1 is 2 mm and the multilayer wiring substrate 100 is bent by 30 degrees (θ=30 degrees), the height d of the level difference is 1 mm.

The angle θ varies depending on the thickness and the Young's modulus of the insulator 13 and the thicknesses and the Young's moduli of the electric conductors 23 and 24, so that the length X1 may be set according to the thicknesses and the Young's moduli of the insulator 13 and the electric conductors 23 and 24.

Therefore, if the wiring substrate is designed so that the height d of the multilayer wiring substrate 100 matches the level difference 501C of the housing 501B (see FIG. 3C), the multilayer wiring substrate 100 may be efficiently disposed inside the housing 501B including the level difference 501C.

FIGS. 4A, 4B, and 5 illustrate part of the cross section instead of the entire multilayer wiring substrate 100, so that much more holes are formed in the actual multilayer wiring substrate 100.

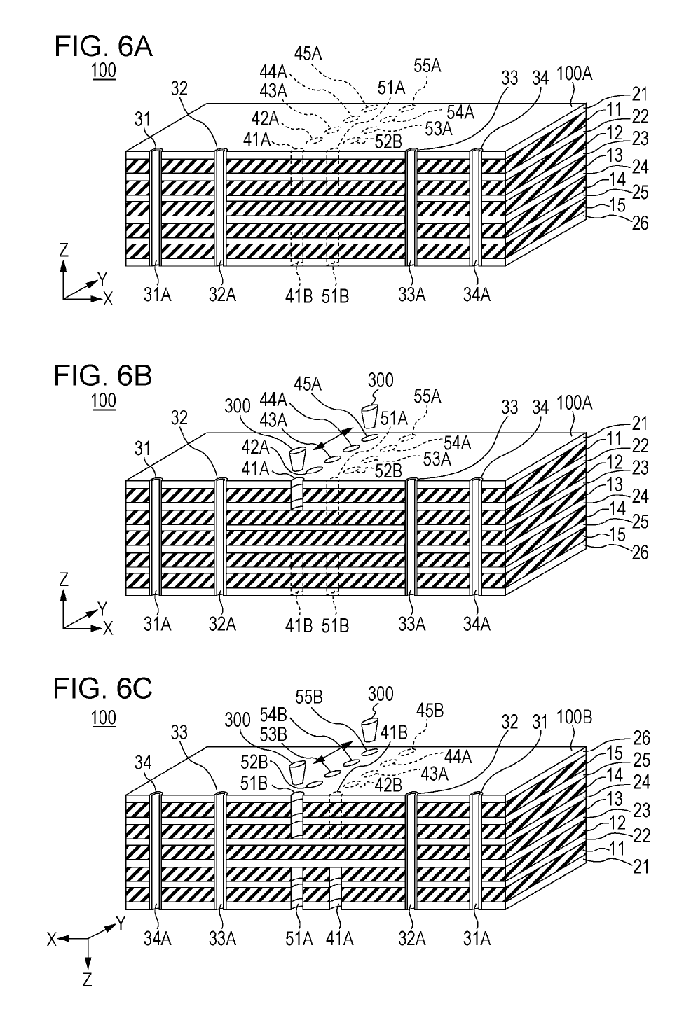

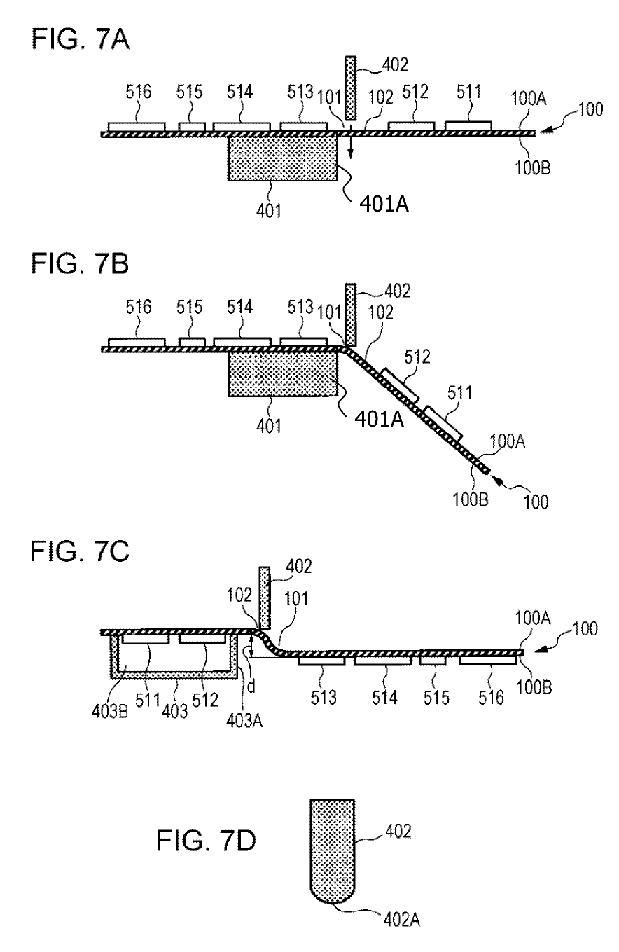

Next, a manufacturing method of the multilayer wiring substrate 100 of the first embodiment will be described with reference to FIGS. 6A, 6B, 6C, 7A, 7B, 7C, and 7D.

FIGS. 6A to 6C are perspective views illustrating a process for forming the holes 41A to 41B and 51A to 55A in the multilayer wiring substrate 100 of the first embodiment.

First, as illustrated in FIG. 6A, positions where the holes 41A to 45A and 51A to 55A are formed on the front surface 100A of the multilayer wiring substrate 100 are determined. The holes 41A to 45A and 51A to 55A are formed by the laser beam machining, so that the center positions, the diameter, and the depth of the holes 41A to 45A and 51A to 55A are determined in the XYZ coordinate system.

As the laser, for example, a carbon dioxide laser or a YAG (Yttrium Aluminum Garnet) laser may be used.

The center positions, the diameter, and the depth of the holes 41B to 45B and 51B to 55B, which are formed on the back surface 100B of the multilayer wiring substrate 100 (see FIG. 6C), are also determined in the XYZ coordinate system.

Next, as illustrated in FIG. 6B, the holes 41A to 45A are sequentially formed by scanning and irradiating the laser 300 to the multilayer wiring substrate 100. After the holes 41A to 45A are formed, the holes 51A to 55A are formed by scanning and irradiating the laser 300 to the multilayer wiring substrate 100.

Here, the scanning of the laser 300 may be performed by, for example, a laser scanner device including a galvanometer mirror. The laser 300 oscillated from a laser oscillator is scanned by the laser scanner device, the laser 300 is concentrated to a desired diameter by an fθ lens, and the laser 300 is sequentially irradiated to the center position of an area where each of the holes 41A to 45A and 51A to 55A is formed. In this way, the holes 41A to 45A and 51A to 55A may be formed.

After the holes 41A to 45A and 51A to 55A are formed on the front surface 100A of the multilayer wiring substrate 100, as illustrated in FIG. 6C, the multilayer wiring substrate 100 is turned upside down and the laser 300 is irradiated to the multilayer wiring substrate 100, so that the holes 51B to 55B are formed and then the holes 41B to 45B are formed.

When the holes 41A to 45A, 41B to 45B, 51A to 55A, and 51B to 55B are formed, the electric conductor 23 or 24 is exposed inside each hole. When the electric conductors 23 and 24 are a copper foil, for example, an organic coating having a thickness of 0.2 μm to 0.3 μm may be formed on the surface of the electric conductors 23 and 24 in each hole by impregnating the multilayer wiring substrate 100 with an organic acid solution for rust-proofing.

Thereby, the process for forming the holes 41A to 45A, 41B to 45B, 51A to 55A, and 51B to 55B in the multilayer wiring substrate 100 is completed. The holes 41A to 45A, 41B to 45B, 51A to 55A, and 51B to 55B are formed into a perforation-like shape.

The output power, the diameter, the irradiation time, the number of shots (the number of irradiations), and the like of the laser 300 used to form the holes 41A to 45A, 41B to 45B, 51A to 55A, and 51B to 55B vary depending on the material, the thickness, the density, and the like of the insulators 11 to 15 and the electric conductors 21 to 26.

Therefore, data of the output power, the diameter, the irradiation time, the number of shots, and the like of the laser used to form the holes 41A to 45A, 41B to 45B, 51A to 55A, and 51B to 55B may be acquired in advance according to the material, the thickness, the density, and the like of the insulators 11 to 15 and the electric conductors 21 to 26. The holes 41A to 45A, 41B to 45B, 51A to 55A, and 51B to 55B may be formed by using the data of the output power, the diameter, the irradiation time, the number of shots, and the like of the laser, which is acquired in advance.

The output power of the laser 300 to penetrate the insulators 11, 12, 14, and 15 is smaller than the output power of the laser 300 to penetrate the electric conductors 21, 22, 25, and 26.

Therefore, in a process for forming the holes in the insulators 11, 12, 14, and 15, when the laser 300 reaches the electric conductors 21 to 26, the laser 300 is reflected by the electric conductors 21 to 26, so that it is possible to detect that the process of the holes reaches each of the electric conductors 21 to 26.

Therefore, when the laser 300 reaches the electric conductor 21, 22, 25, or 26, the output power of the laser 300 is increased and the process may be performed to penetrate the electric conductor 21, 22, 25, or 26, and when the laser reaches the electric conductor 23 or 24, the process may be finished.

The process is performed while adjusting the output power of the laser 300 in this way, so that the holes 41A to 45A, 41B to 45B, 51A to 55A, and 51B to 55B may be formed, while the electric conductor 23, the insulator 13, and the electric conductor 24 are left.

The process by the laser 300 may be performed at high speed after setting the diameter of the holes 41A to 45A, 41B to 45B, 51A to 55A, and 51B to 55B to, for example, one in the range 50 μm to 400 μm. Therefore, fine holes may be formed in a short time.

Although, here, a method for forming the holes 41A to 45A, 41B to 45B, 51A to 55A, and 51B to 55B by using the laser 300 is described, the holes 41A to 45A, 41B to 45B, 51A to 55A, and 51B to 55B may be formed by using a drill.

When forming the holes by a drill, for example, a drill for forming the through-holes 31A to 34A of the vias 31 to 34 may be used. The diameter of the holes 41A to 45A, 41B to 45B, 51A to 55A, and 51B to 55B is determined by the diameter of the drill. The depth of the holes 41A to 45A, 41B to 45B, 51A to 55A, and 51B to 55B may be controlled by the amount of feeding of the drill in the Z axis direction.

The holes 41A to 45A, 41B to 45B, 51A to 55A, and 51B to 55B are formed by using the laser 300 or a drill, so that high-density, which is not realized by the flexible substrate 3 of the comparative example (see FIG. 1), may be realized.

Next, a bending process for bending the multilayer wiring substrate 100 will be described with reference to FIG. 7.

FIGS. 7A, 7B, 7C, and 7D are diagrams illustrating a bending process for bending the multilayer wiring substrate 100 of the first embodiment. FIGS. 7A to 7C are side views illustrating step by step the bending process for bending the multilayer wiring substrate 100 of the first embodiment. FIG. 7D is a front view illustrating one of tools used in the process illustrated in FIG. 7A.

Here, a method for performing the bending process after mounting the RF communication unit 511, the AD converter 512, the baseband processor 513, the CPU 514, the I/F 515, and the memory 516 on the multilayer wiring substrate 100 of the first embodiment will be described.

As illustrated in FIGS. 7A to 7C, tools 401, 402, and 403 are used in the bending process of the multilayer wiring substrate 100 of the first embodiment.

The tool 401 is a tool used as a pedestal, and for example, a rectangular solid metal plate may be used as the tool 401. The tool 401 may have a thickness larger than the level difference d to be generated in the multilayer wiring substrate 100 by the bending process. For example, a metal plate of copper or iron, or a hard resin molded article may be used as the tool 401. The tool 401 may be a metal plate, on the surface of which a resin is coated. The resin or the resin coated on the metal is to reduce damage to the wiring substrate. The tool 401 is used when bending the bending portion 101.

The tool 402 is attached to a rise and fall type pressing mechanism. In FIG. 7A, the tool 402 may rise and fall at a position away from the right side surface 401A of the tool 401 by a predetermined distance.

The tool 403 is a pedestal having a squared U shape including a concave portion 403B obtained by hollowing out the tool 401 from the front surface. The tool 403 is used when bending the bending portion 102.

Here, the holes 41A to 45A and 41B to 45B are formed in the bending portion 101 and the holes 51A to 55A and 51B to 55B are formed in the bending portion 102. The bending portions 101 and 102 are portions where the rigidity is low in the multilayer wiring substrate 100 due to the holes 41A to 45A and 41B to 45B and the holes 51A to 55A and 51B to 55B.

First, as illustrated in FIG. 7A, positioning is performed so that the bending portion 101 of the multilayer wiring substrate 100 is located between the right side surface 401A of the tool 401 and the tool 402, and then the portion on the left side of the bending portion 101 of the multilayer wiring substrate 100 is mounted on the tool 401. At this time, the tool 402 is located above the multilayer wiring substrate 100 before the bending process is performed.

Next, as illustrated in FIG. 7B, the tool 402 is lowered by the pressing mechanism and the tool 402 presses the multilayer wiring substrate 100 downward while the tool 402 is in contact with the front surface 100A of the multilayer wiring substrate 100, so that a shearing stress is generated at the bending portion 101 of the multilayer wiring substrate 100. Thereby, as illustrated in FIG. 7B, the portion on the right side of the bending portion 101 of the multilayer wiring substrate 100 is bent downward.

Finally, the multilayer wiring substrate 100 is turned upside down and the portion on the left side of the bending portion 102 of the multilayer wiring substrate 100 is mounted on the tool 403. At this time, to reduce damage of the RF communication unit 511 and the AD converter 512, the multilayer wiring substrate 100 may be mounted on the tool 403 so that the RF communication unit 511 and the AD converter 512 are housed inside the concave portion 403B.

The tool 403 is disposed at the same position as the tool 401 illustrated in FIGS. 7A and 7B with respect to the tool 402 and the tool 402 may rise and fall at a position away from the right side surface 403B of the tool 403 by a predetermined distance.

Positioning is performed so that the bending portion 102 of the multilayer wiring substrate 100 is located between the right side surface 403B of the tool 403 and the tool 402, and then the tool 402 is lowered by the pressing mechanism. The tool 402 is further pressed downward while the tool 402 is in contact with the back surface 100B of the multilayer wiring substrate 100, so that a shearing stress is generated at the bending portion 102 of the multilayer wiring substrate 100.

Thereby, as illustrated in FIG. 7C, the bending portion 102 of the multilayer wiring substrate 100 is bent and a level difference having the height d may be formed.

Here, as illustrated in FIG. 7D, a bottom portion 402A of the tool 402 may be rounded so that the central portion in the width direction is convex downward. If the bottom portion 402A is rounded in this way, when bending the multilayer wiring substrate 100, it is possible to gradually generate a shearing stress from the central portion in the width direction of the multilayer wiring substrate 100 to both ends, so that the multilayer wiring substrate 100 may be efficiently bent.

As described above, according to the first embodiment, the holes 41A to 45A, 41B to 45B, 51A to 55A, and 51B to 55B are formed after the multilayer wiring substrate 100 is completed, so that the bending process may be performed and the bending structure of the multilayer wiring substrate 100 may be easily manufactured.

If it is possible to mount the RF communication unit 511, the AD converter 512, the baseband processor 513, the CPU 514, the I/F 515, and the memory 516 on the multilayer wiring substrate 100 after the multilayer wiring substrate 100 is bent, the above components may be mounted after the multilayer wiring substrate 100 is bent.

As described above, according to the first embodiment, the holes 41A to 45A, 41B to 45B, 51A to 55A, and 51B to 55B are formed after the multilayer wiring substrate 100 is completed, so that the bending structure may be easily manufactured in the rigid type multilayer wiring substrate 100 including the insulators 11, 12, 13, 14, and 15.

A conventional rigid type wiring substrate has high rigidity (for example, about 30 GPa) and is difficult to bend, so that, for example, if there is a level difference having a height of only about 0.1 mm, the wiring substrate is difficult to be used in an electronic device.

On the other hand, the multilayer wiring substrate 100 of the first embodiment may be bent according to the height of the level difference, so that it is possible to effectively use space inside the housing 501B including the level difference 501C (see FIG. 3).

The multilayer wiring substrate 100 is bent by using the holes 41A to 45A, 41B to 45B, 51A to 55A, and 51B to 55B, which may be easily formed by the laser process or the drill process, as the bending portions 101 and 102, so that the number of processes used to bend the multilayer wiring substrate 100 is significantly smaller than that of a conventional wiring substrate.

Therefore, according to the first embodiment, it is possible to provide the multilayer wiring substrate 100 where a bent structure may be easily manufactured.

The multilayer wiring substrate 100 is a rigid type substrate including the insulators 11, 13, and 15 which are prepregs and the insulators 12 and 14 which are cores, so that it is possible to significantly reduce the manufacturing cost compared with the flexible substrate 3 and the rigid flexible substrate 5 of the comparative examples.

The multilayer wiring substrate 100 is a rigid type substrate, so that it is possible to improve the packaging density.

Further, it is possible to downsize the electronic device 1 and reduce the cost of the electronic device 1 by bending the rigid type multilayer wiring substrate 100.

In the above description, a form in which the positions of the holes 41A to 45A are the same as the positions of the holes 41B to 45B in the XY plane is described. However, the positions of the holes 41A to 45A may be different from the positions of the holes 41B to 45B in the XY plane. For example, the holes 41A to 45A and the holes 41B to 45B may be formed so that the holes 41A to 45A and the holes 41B to 45B are located alternately so as not to overlap each other in the Y axis direction.

Similarly, the positions of the holes 51A to 55A may be different from the positions of the holes 51B to 55B in the XY plane. For example, the holes 51A to 55A and the holes 51B to 55B may be formed so that the holes 41A to 45A and the holes 41B to 45B are located alternately so as not to overlap each other in the Y axis direction.

In the above description, a form in which the holes 41A to 45A, 41B to 45B, 51A to 55A, and 51B to 55B are formed with a distance Y1 between them is described. However, the holes 41A to 45A, 41B to 45B, 51A to 55A, and 51B to 55B may be continuously formed in the Y axis direction without the distance Y1 between them.

It is possible to form either the holes 41A to 45A and 51A to 55A on the front surface 100A or the holes 41B to 45B and 51B to 55B on the back surface 100B.

In the above description, a form is described in which the holes 41A to 45A, 41B to 45B, 51A to 55A, and 51B to 55B are formed so that the electric conductor 23, the insulator 13, and the electric conductor 24 are left and the depth of the holes is Z1. However, the holes may be formed in any combination if the holes are formed leaving at least one layer of an electric conductor (prepreg or core) and at least one layer of an insulator. Therefore, the depth Z1 of the holes 41A to 45A, 41B to 45B, 51A to 55A, and 51B to 55B may be set to any value if the holes are formed leaving at least one layer of an electric conductor (prepreg or core) and at least one layer of an insulator. In other words, the depth of the holes 41A to 45A and 51A to 55A which are formed from the front surface 100A may be different from the depth of the holes 41B to 45B and 51B to 55B which are formed from the back surface 100B.

In this case, the insulator and the electric conductor left between the holes 41A to 45A and the holes 41B to 45B may be different from the insulator and the electric conductor left between the holes 51A to 55A and the holes 51B to 55B.

The thickness of the insulator (any one of 11 to 15) left between the holes 41A to 45A and the holes 41B to 45B and between the holes 51A to 55A and holes 51B to 55B may be set to the same as the thickness of the flexible substrate 3 of the comparative example (see FIG. 1). It is possible to bend the insulator (any one of 11 to 15) by setting the thickness as described above. When a plurality of insulators (some of 11 to 15) are left, the total thickness of the plurality of insulators (some of 11 to 15) may be set to the same as the thickness of the flexible substrate 3 of the comparative example (see FIG. 1).

In the above description, a form is described in which the holes 41A to 45A, 41B to 45B, 51A to 55A, and 51B to 55B are formed to be arranged on the same straight line along the Y axis, respectively. However, the holes 41A to 45A, 41B to 45B, 51A to 55A, and 51B to 55B may be formed to be arranged non-linearly with respect to the Y axis. For example, the holes 41A to 45A, 41B to 45B, 51A to 55A, and 51B to 55B may be arranged in an arc shape or in an S-shape.

In the above description, a form is described in which two rows of the holes 41A to 45A, 41B to 45B, 51A to 55A, and 51B to 55B are formed in the X axis direction. However, the number of the rows may be one, or there or more. The number of the rows of the holes may be determined according to the number of bending portions in the multilayer wiring substrate 100. The form in which the number of the rows is one will be described later as a second embodiment.

In the above description, a form is described in which the shape of the holes 41A to 45A, 41B to 45B, 51A to 55A, and 51B to 55B is a circle in plan view. However, the holes may be elongate holes which have an elongated shape in plan view. For example, when forming holes by laser beam machining, an elongate hole obtained by connecting and integrating the hole 41A and 42A may be formed by irradiating the laser to an area from the position of the hole 41A to the position of the hole 42A. Such an elongate hole may be formed by connecting the holes in any combination of the holes 42A to 45A. This is the same for the holes 41B to 45B, 51A to 55A, and 51B to 55B.

### Second Embodiment

A multilayer wiring substrate 200 of the second embodiment is different from the multilayer wiring substrate 100 of the first embodiment in a point that the multilayer wiring substrate 200 has one bending portion. Specifically, the multilayer wiring substrate 200 of the second embodiment is different from the multilayer wiring substrate 100 of the first embodiment in a point that the holes 51A to 55A and 51B to 55B are not formed in the multilayer wiring substrate 200, although the holes 41A to 45A and 41B to 45B are formed in the same manner as in the multilayer wiring substrate 100.

Hereinafter, the same reference numerals are given to the same constituent elements as those in the multilayer wiring substrate 100 of the first embodiment and the description thereof will be omitted.

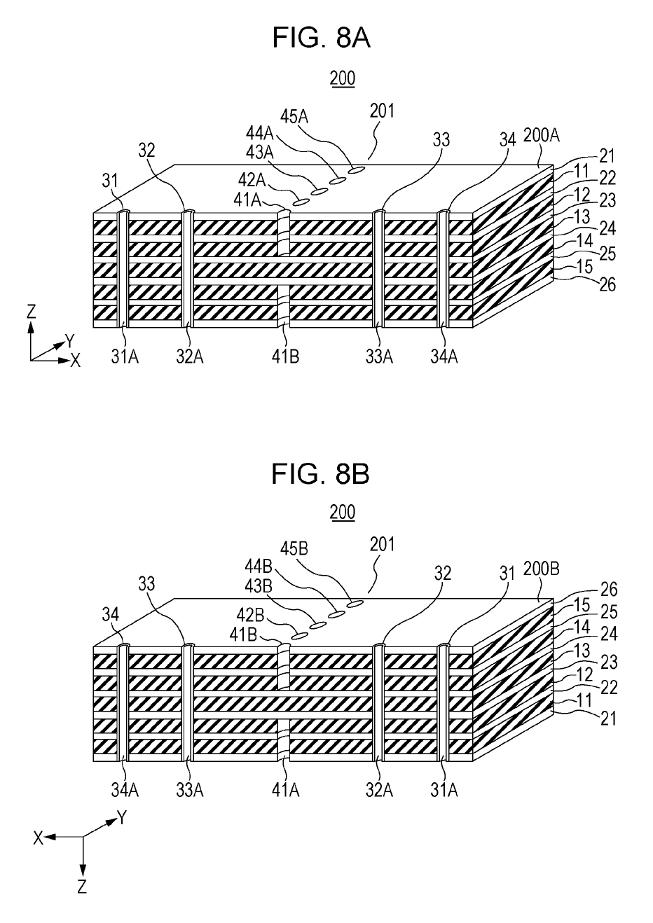

FIGS. 8A and 8B are perspective views illustrating a cross section structure of the multilayer wiring substrate 200 of the second embodiment.

A cross section structure of the multilayer wiring substrate 200 illustrated in FIGS. 8A and 8B is an enlarged view of a part of a cross section of the multilayer wiring substrate 200 before being bent.

The multilayer wiring substrate 200 of the second embodiment includes five layers of insulators 11 to 15, six layers of electric conductors 21 to 26, and vias 31 to 34. The multilayer wiring substrate 200 further includes holes 41A to 45A and 41B to 45B.

The holes 41A to 45A and 41B to 45B are included in a bending portion 201. The multilayer wiring substrate 200 of the second embodiment may be bent at the bending portion 201.

Therefore, when the multilayer wiring substrate 200 is not bent, the multilayer wiring substrate 200 is difficult to be housed inside the housing 2 of the small electronic device 1 (see FIG. 3). However, when the multilayer wiring substrate 200 may be housed inside the housing 2 by bending the multilayer wiring substrate 200 at the bending portion 201, it is possible to effectively use space inside the housing 2.

As described above, according to the second embodiment, the holes 41A to 45A and 41B to 45B are formed after the multilayer wiring substrate 200 is completed, so that the bending structure may be easily manufactured in the rigid type multilayer wiring substrate 200 including the insulators 11, 13, and 15 which are prepregs and the insulators 12 and 14 which are cores.

The multilayer wiring substrate 200 is bent by using the holes 41A to 45A and 41B to 45B, which may be easily formed by the laser process or the drill process, as the bending portion 201, so that the number of processes used to bend the multilayer wiring substrate 200 is significantly smaller than that of a conventional wiring substrate.

Therefore, according to the second embodiment, it is possible to provide the multilayer wiring substrate 200 where a bent structure is easily manufactured.

The multilayer wiring substrate 200 is a rigid type substrate including the insulators 11, 13, and 15 which are prepregs and the insulators 12 and 14 which are cores, so that it is possible to significantly reduce the manufacturing cost compared with the flexible substrate 3 and the rigid flexible substrate 5 of the comparative examples.

The multilayer wiring substrate 200 is a rigid type substrate, so that it is possible to improve the packaging density.

Although the wiring substrate, the electronic device, and the manufacturing method of wiring substrate of the exemplary embodiments of the present disclosure have been described, the present disclosure is not limited to the specifically disclosed embodiments, but various changes and modifications are possible without departing from the scope of the claims.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A multilayer wiring substrate comprising:
a plurality of insulator layers; and
electric conductors, the electric conductors and the plurality of insulator layers being configured to be stacked alternately,
wherein a plurality of holes are formed from a surface of the multilayer wiring substrate in a thickness direction of the multilayer wiring substrate, the holes being formed leaving at least one of the insulators.

2. The multilayer wiring substrate according to claim 1,
wherein the holes are formed from the surface and the other surface of the multilayer wiring substrate in the thickness direction of the multilayer wiring substrate, and
the holes formed from the surface and the holes formed from the other surface are alternately arranged in plan view.

3. An electronic device comprising:
a multilayer wiring substrate, the multilayer wiring substrate including,
a plurality of insulator layers; and
electric conductors, the electric conductors and the plurality of
insulator layers being configured to be stacked alternately,
wherein a plurality of holes are formed from a surface of the multilayer wiring substrate in a thickness direction of the multilayer wiring substrate, the holes being formed leaving at least one of the insulators; and
an electronic component mounted on the multilayer wiring substrate.

4. A manufacturing method of a multilayer wiring substrate, the method comprising:
forming a hole that is formed from a surface of a multilayer wiring substrate in a thickness direction of the multilayer wiring substrate while leaving at least one of a plurality of insulator layers, the multilayer wiring substrate including the plurality of insulator layers and electric conductors, the plurality of insulator layers and the electric conductors being stacked alternately.

5. The manufacturing method of a multilayer wiring substrate according to claim 4, further comprising bending the multilayer wiring substrate at the hole.
